(19) United States
(12) Patent Application Publication
(10) Pub. No.: US 2025/0167338 A1
(43) Pub. Date: May 22, 2025

(54) BATTERY DISCONNECT UNIT

(71) Applicant: Panasonic Intellectual Property Management Co., Ltd., Osaka (JP)

(72) Inventor: Aki SASAKURA, Osaka (JP)

(21) Appl. No.: 18/836,806

(22) PCT Filed: Feb. 17, 2023
(86) PCT No.: PCT/JP2023/005702

§ 371 Date: Aug. 8, 2024

Related U.S. Application Data
(60) Provisional application No. 63/313,306, filed on Feb. 24, 2022.

(51) Int. Cl. H01M 10/6553; H01M 10/625; H01M 10/651; H01M 10/6567; H01M 50/583

(52) U.S. Cl. CPC H01M 10/6553; H01M 10/651; H01M 10/6567; H01M 50/583; H01M 10/625

(57) ABSTRACT

A battery disconnect unit includes: a fuse; a busbar connected to a terminal of the fuse; and a heatsink that is in contact with the terminal of the fuse. The terminal of the fuse is located between the busbar and the heatsink. The terminal of the fuse, the busbar, and the heatsink are fastened together by a screw that is an example of a fastening member.

### TECHNICAL FIELD

The present disclosure relates to a battery disconnect unit.

### BACKGROUND ART

An automobile or an electric appliance includes a power control unit that includes a power device. Known examples of the power control unit include a battery disconnect unit (BDU) that is capable of supplying or disconnecting power outputted from a battery. For example, such a battery disconnect unit is included in a drive system of an electric vehicle, such as a hybrid electric vehicle or a pure electric vehicle (see Patent Literature (PTL) 1).

Such a drive system of an electric vehicle includes: a battery that outputs direct-current power as drive energy for driving the electric vehicle; a battery disconnect unit that controls supply and disconnection of the direct-current power outputted from the battery; an inverter that converts the direct-current power supplied from the battery disconnect unit to alternating-current power; and a motor that rotationally drives the wheels of the vehicle using the alternating-current power outputted from the inverter.

The battery disconnect unit includes electronic components such as a relay and a fuse. In the battery disconnect unit, the relay switches between disconnection and supply of the direct-current power from the battery to the inverter. The fuse disconnects the circuit when anomalous current occurs. Each of a terminal of the relay and a terminal of the fuse is connected to a busbar.

### CITATION LIST

### Patent Literature

[PTL 1] Japanese Unexamined Patent Application Publication No. 2017-28991

### SUMMARY OF INVENTION

### Technical Problem

In the battery disconnect unit, heat is generated by the fuse. However, in the conventional battery disconnect unit, a distance from a terminal of the fuse, which is a heat generation source, to a heat transfer path along the current path of the busbar is too long to allow the heat generated by the fuse to be sufficiently dissipated.

In particular, since short-time rapid generation of heat is greatly influenced by the heat capacity in the vicinity of the heat generation source, it is difficult to suppress short-time temperature increase by a heat dissipation technique of dissipating heat at a part away from a fastening part where the terminal of the fuse and the busbar are fastened together.

Moreover, the battery disconnect unit needs to have an insulation structure providing sufficient clearance and creepage distances corresponding to a large current or a high voltage. However, such an insulation structure may inhibit heat dissipation and also increase the size of the battery disconnect unit. More specifically, to enable both heat dissipation and insulation, the battery disconnect unit has to increase in size unfortunately.

To response to the above issue, it is an object of the present disclosure to provide a battery disconnect unit that is capable of achieving downsizing while enabling both heat dissipation and insulation.

### Solution to Problem

In order to achieve the above object, a battery disconnect unit includes: a fuse; a busbar connected to a terminal of the fuse; and a heatsink that is in contact with the terminal of the fuse. The terminal of the fuse is located between the busbar and the heatsink. The terminal of the fuse, the busbar, and the heatsink are fastened together by a fastening member.

### Advantageous Effects of Invention

The present disclosure provides a battery disconnect unit that is capable of achieving downsizing while enabling both heat dissipation and insulation.

### BRIEF DESCRIPTION OF DRAWINGS

FIG. 1 is a block diagram illustrating a drive system according to Embodiment.

FIG. 2 is an external perspective view of a battery disconnect unit according to Embodiment.

FIG. 3 is a perspective view of the battery disconnect unit with its upper cover removed.

FIG. 4 is a perspective exploded view of the battery disconnect unit according to Embodiment.

FIG. 5 is a cross-sectional view of the battery disconnect unit according to Embodiment taken along a plane slicing through screws inserted in terminals of a relay.

FIG. 6 is a cross-sectional view of the battery disconnect unit according to Embodiment taken along a plane slicing through screws inserted in terminals of a fuse.

FIG. 7 is an enlarged cross-sectional view of region VII enclosed by the broken line in FIG. 5.

FIG. 8 is an enlarged cross-sectional view of region VIII enclosed by the broken line in FIG. 6.

FIG. 9 is a cross-sectional view of a battery disconnect unit according to Variation 1.

FIG. 10 is a cross-sectional view of a battery disconnect unit according to Variation 2.

FIG. 11 is a cross-sectional view of a battery disconnect unit according to Variation 3.

FIG. 12 is a diagram illustrating a construction of a module structure included in a battery disconnect unit according to Variation 4.

FIG. 13 is a cross-sectional view of the battery disconnect unit according to Variation 4.

### DESCRIPTION OF EMBODIMENT

Hereinafter, a certain exemplary embodiment will be described with reference to the accompanying Drawings. The following embodiment is a specific example of the present disclosure. The numerical values, shapes, materials, elements, arrangement and connection configuration of the elements, steps, the order of the steps, etc., described in the following embodiment are merely examples, and are not intended to limit the present disclosure. Among elements in the following embodiment, those not described in any one of the independent claims indicating the broadest concept of the present disclosure are described as optional elements.

Note that the respective figures are schematic diagrams and are not necessarily precise illustrations. Additionally, components that are essentially the same share like reference signs in the figures. Furthermore, in the Description, the terms “below” and “above” do not necessarily mean an upper direction (vertically above) and a lower direction (vertically below) in the absolute spatial recognition.

### Embodiment

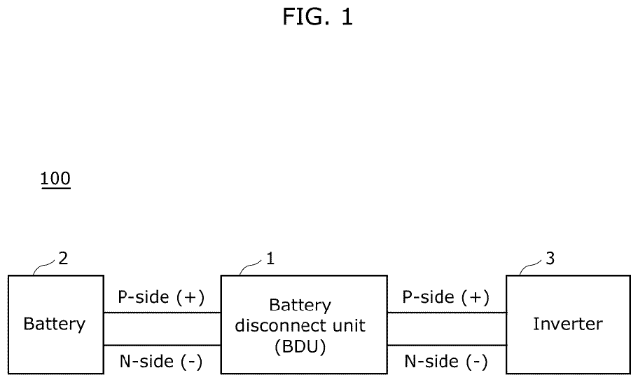

Drive system 100 is first described as an example of a system that includes battery disconnect unit 1 according to Embodiment. FIG. 1 is a block diagram illustrating drive system 100 according to Embodiment.

As illustrated in FIG. 1, drive system 100 includes battery disconnect unit 1, battery 2, and inverter 3.

Battery disconnect unit 1 is an example of a power control unit. Battery disconnect unit 1 is connected between battery 2 and inverter 3 to disconnect direct-current power of battery 2 or supply the direct-current power of battery 2 to inverter 3. To be more specific, battery disconnect unit 1 is able to switch between: a power supplied state in which power is supplied to inverter 3; and a power disconnected state in which power to inverter 3 is disconnected.

Note that, although not illustrated, battery disconnect unit 1 may be connected not only to inverter 3 but also to a quick charging circuit. In this case, battery disconnect unit 1 is able to switch the output destination of the direct-current power of battery 2 between inverter 3 and the quick charging circuit. Furthermore, in this case, battery disconnect unit 1 is also able to switch between: a power supplied state in which power is supplied to the quick charging circuit; and a power disconnected state in which power to the quick charging circuit is disconnected.

Battery 2 is a power storage device, such as a secondary battery. Battery 2 outputs direct-current power. Thus, battery 2 connected to battery disconnect unit 1 supplies the direct-current power to battery disconnect unit 1. Examples of battery 2 include, but not limited to, a lithium-ion secondary battery.

Inverter 3 is an AC/DC converter, and converts direct-current power supplied from battery disconnect unit 1 to alternating-current power. Although not illustrated, inverter 3 is connected to a motor, for example. The motor connected to inverter 3 is driven using the alternating-current power outputted from inverter 3.

Drive system 100 having the above configuration is provided to an electric vehicle, such as a hybrid electric vehicle or a pure electric vehicle, for example. More specifically, battery disconnect unit 1 is provided to an electric vehicle. In this case, the direct-current power outputted from battery 2 is supplied to inverter 3 via battery disconnect unit 1 to be converted to alternating-current power used as drive energy for driving the electric vehicle. The alternating-current power outputted from inverter 3 is supplied to the motor for rotationally driving the wheels of the vehicle.

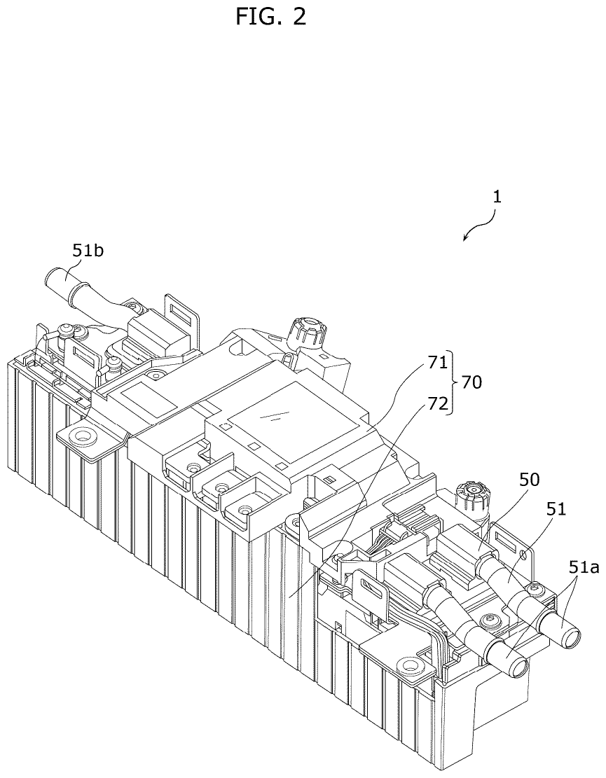

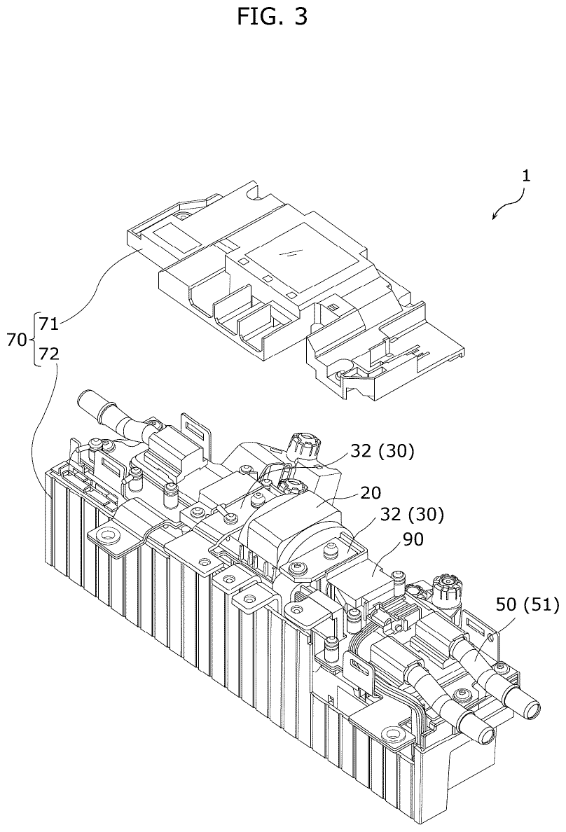

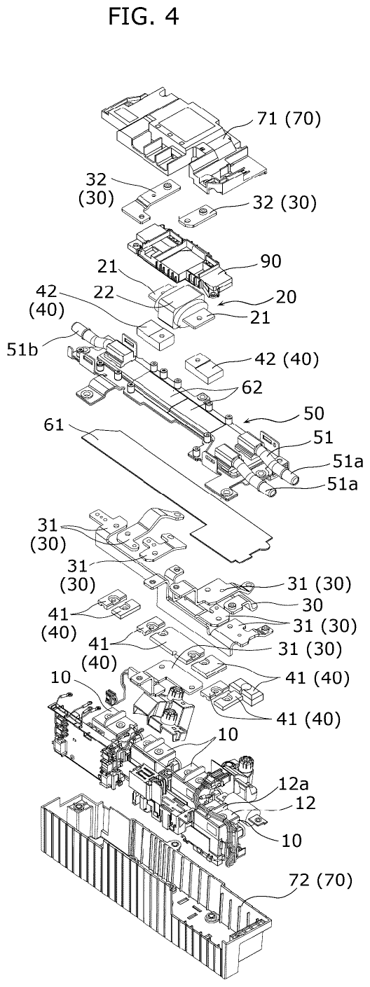

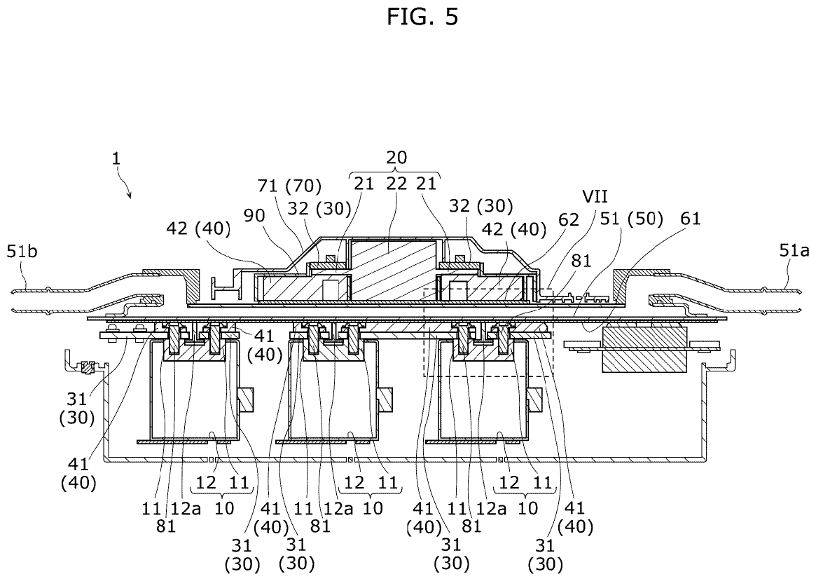

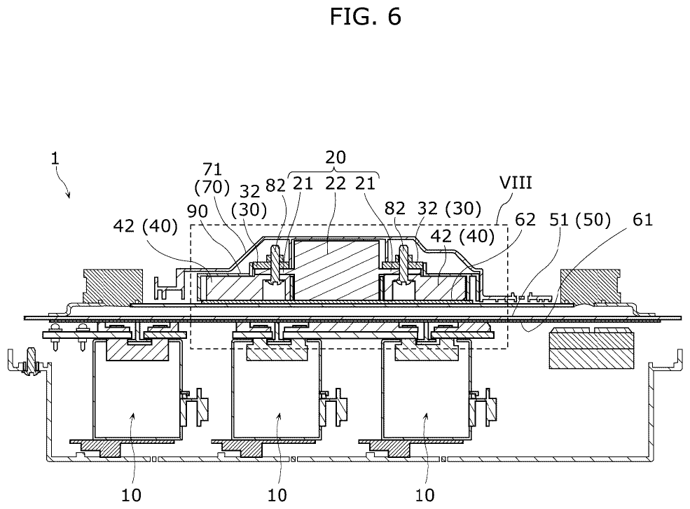

Next, the structure of battery disconnect unit 1 according to Embodiment is described with reference to FIG. 2 to FIG. 4 and also to FIG. 1. FIG. 2 is an external perspective view of battery disconnect unit 1 according to Embodiment. FIG. 3 is a perspective view of battery disconnect unit 1 with upper cover 71 removed. FIG. 4 is a perspective exploded view of battery disconnect unit 1 according to Embodiment. Each of FIG. 5 and FIG. 6 is a cross-sectional view of battery disconnect unit 1 according to Embodiment. FIG. 5 is a cross-sectional view taken along a plane slicing through screws 81. FIG. 6 is a cross-sectional view taken along a plane slicing through screws 82. Note that screws, such as screws 81 and 82, are omitted from FIG. 4. Note also that each of FIG. 5 and FIG. 6 basically illustrates only a part visible in the cross section.

As illustrated in FIG. 2 to FIG. 6, battery disconnect unit 1 includes relay 10 and fuse 20. Note that, in addition to relay 10 and fuse 20, battery disconnect unit 1 may also include electronic components, such as a current sensor and a resistor.

Relay 10 is an electronic component having a function of enabling and disabling conduction. More specifically, relay 10 has a function of switching between: supplying, to inverter 3, the direct-current power supplied from battery 2 to battery disconnect unit 1; and disconnecting the direct-current power to inverter 3. Relay 10 is an example of a power device, and generates heat. In other words, relay 10 is a heat generating component that generates heat.

As illustrated in FIG. 5, relay 10 includes: a pair of terminals 11; and case 12 that is insulating and includes the pair of terminals 11 fixed therein. Each of the pair of terminals 11 is a fixed terminal. Furthermore, each of the pair of terminals 11 is an external connection terminal that is connected to an external member. To be more specific, each of the pair of terminals 11 is connected to busbar 30. Each of the pair of terminals 11 is a metallic terminal made of a metallic material. Note that although the pair of terminals 11 appears to be integrated as a single member in FIG. 5, terminals 11 are electrically separated from each other by an insulating member inserted between this pair of terminals 11.

Although not illustrated, relay 10 includes a movable contact that comes into contact with or separates from one of the pair of terminals 11 that are fixed terminals. This movable contact coming into contact with or separating from the fixed terminal allows relay 10 to supply or disconnect the current.

Case 12 is a resin case made of a resin material, for example. The movable contact is accommodated in case 12. In the present embodiment, relay 10 further includes insulating plate 12a located between the pair of terminals 11. Insulating plate 12a is an insulating wall that divides the pair of terminals 11. To be more specific, insulating plate 12a is a part of case 12 and disposed in an upright position on an upper plate of case 12.

At least one relay 10 is disposed in battery disconnect unit 1. In the present embodiment, battery disconnect unit 1 includes a plurality of relays 10. The plurality of relays 10 include: a P-side first main relay corresponding to a P-side electrode of battery 2; and an N-side second main relay corresponding to an N-side electrode of battery 2. Note that, for battery disconnect unit 1 including the quick charging circuit, the plurality of relays 10 may include a P-side first QC relay corresponding to the P-side electrode of battery 2; and an N-side second QC relay corresponding to the N-side electrode of battery 2.

Fuse 20 is an electronic component having a function of interrupting the circuit in the event of abnormal current. For example, fuse 20 has a function of disconnecting the current in the event of overcurrent. Fuse 20 is a heat generating component that generates heat.

As illustrated in FIG. 5, fuse 20 includes a pair of terminals 21 and case 22. Each of the pair of terminals 21 is an external connection terminal that is connected to an external member. To be more specific, each of the pair of terminals 21 is connected to busbar 30. Each of the pair of terminals 21 is a metallic terminal made of a metallic material. The pair of terminals 21 is disposed in case 22 to project from side surfaces of case 22. In the present embodiment, fuse 20 is of a passive type and is a blow-type fuse (a current fuse) that blows in the event of overcurrent. In this case, case 22 includes a blow section. Note that fuse 20 is not limited to the passive-type fuse and may be an active-type fuse from which the current is disconnected in response to a control signal. The active-type fuse is a pyro fuse, for example.

Furthermore, as illustrated in FIG. 2 to FIG. 6, battery disconnect unit 1 includes busbar 30, heatsink 40, cooler 50, insulating sheets 61 and 62, and enclosure 70.

Busbar 30 is a wiring member through which current flows, and makes up a conducting path. Busbar 30 is connected to the electronic components included in battery disconnect unit 1. The passage of current through busbar 30 causes busbar 30 to generate heat.

At least one busbar 30 is disposed in battery disconnect unit 1. In the present embodiment, a plurality of busbars 30 are disposed as illustrated in FIG. 4 to FIG. 6. For example, the plurality of busbars 30 include busbar 31 (a first busbar) that is connected to relay 10. In this case, busbar 31 is connected to terminal 11 of relay 10. To be more specific, busbar 31 is connected to terminal 11 (the fixed terminal) of relay 10. Furthermore, the plurality of busbars 30 include busbar 32 (a second busbar) that is connected to fuse 20. In this case, busbar 32 is connected to terminal 21 of fuse 20.

The plurality of busbars 30 include: an internal busbar that is disposed completely within enclosure 70; and an external busbar that is disposed to be partially exposed from enclosure 70. The internal busbar connects two electronic components, for example. In this case, one end part of the internal busbar is connected to one of the two electronic components and the other end part of the internal busbar is connected to the other of the two electronic components. The external busbar is connected to one electronic component, for example. In this case, one end part of the external busbar is connected to the electronic component and the other end part of the external busbar is an external connection terminal of battery disconnect unit 1. Thus, the other end part of the external busbar is exposed on the outside of enclosure 70. Each of busbar 31 connected to relay 10 and busbar 32 connected to fuse 20 may be either an internal busbar or an external busbar.

Busbar 30 is the wiring member carrying the current, and thus is made of an electrical conducting material. For example, busbar 30 is a metallic rigid body made of a metallic material, such as copper or aluminum. In the present embodiment, busbar 30 is made of copper. To be more specific, busbar 30 is a metallic plate of uniform thickness, made of pure copper or a copper alloy. Bending a flat metal plate stamped into a predetermined shape by, for instance, press working forms busbar 30 having a predetermined three-dimensional shape.

Note that busbar 30 is fastened to another member with a screw, such as a bolt or a vis, and thus a part of each busbar 30 has an insertion hole as a screw hole into which the screw is inserted. For example, busbar 30 has this insertion hole in an end part of busbar 30.

Heatsink 40 is a heat dissipation member that dissipates (diffuses) heat generated by a heat generator, such as a heat generating component. In the present embodiment, battery disconnect unit 1 includes a plurality of heatsinks 40 as illustrated in FIG. 4 to FIG. 6. To be more specific, the plurality of heatsinks 40 include: heatsink 41 (a first heatsink) that dissipates heat generated by relay 10; and heatsink 42 (a second heatsink) that dissipates heat generated by fuse 20.

As illustrated in FIG. 5, heatsink 41 that dissipates the heat of relay 10 is disposed near relay 10. Thus, the heat generated by relay 10 is conducted to heatsink 41 that then dissipates the heat. In the present embodiment, heatsink 41 is disposed above relay 10. To be more specific, two heatsinks 41 are disposed above case 12 of one relay 10.

As illustrated in FIG. 6, heatsink 42 that dissipates the heat generated by fuse 20 is disposed near fuse 20. Thus, the heat generated by fuse 20 is conducted to heatsink 42 that then dissipates the heat. In the present embodiment, heatsink 42 is disposed lateral to fuse 20. To be more specific, heatsink 42 is disposed on each of both sides of case 22 of one fuse 20. Thus, fuse 20 is located between two heatsinks 42. Fuse 20 and two heatsinks 42 are placed side by side.

Heatsink 40 may be made of a material having high heat conductivity. For example, heatsink 40 may be made of a metallic material, such as aluminum or copper, or a resin material having high heat conductivity. In the present embodiment, heatsink 40 is a metallic block made of aluminum.

Cooler 50 cools the inside of battery disconnect unit 1. In the present embodiment, cooler 50 is a coolant plate that cools the inside of battery disconnect unit 1 through water cooling. Cooler 50 cools heatsink 41 to which the heat generated by relay 10 is conducted and also cools heatsink 42 to which the heat generated by fuse 20 is conducted. As illustrated in FIG. 5 and FIG. 6, relay 10 is disposed below cooler 50, and fuse 20 is disposed above cooler 50.

As illustrated in FIG. 2 to FIG. 6, cooler 50, which is the coolant plate, includes passage 51 through which coolant water flows, for example. To be more specific, cooler 50 includes, as passage 51, a metallic pipe through which coolant water flows. Examples of a metallic material for making passage 51 include copper, aluminum, and stainless steel.

The coolant water of cooler 50 flows through passage 51 in only one direction. In the present embodiment, passage 51 includes two end openings 51a at one end of passage 51 and one end opening 51b at the other end of passage 51. Two end openings 51a merge midway in passage 51. One from between the pair of two end openings 51a and one end opening 51b is a supply opening (an upstream opening) to which the coolant water is supplied. The other from between the pair of two end openings 51a and one end opening 51b is a discharge opening (a downstream opening) from which the coolant water is discharged.

Note that although passage 51 includes two end openings 51a at the one end of passage 51, this is not intended to be limiting. For example, passage 51 may include one end opening at each of the one end and the other end. Alternatively, passage 51 may include a plurality of end openings at each of the one end and the other end. Furthermore, to circulate the coolant water flowing through passage 51, end opening 51a and end opening 51b may be connected via an external passage (pipe). In this case, the external passage that connects end opening 51a with end opening 51b may include a heat exchanger.

Cooler 50 includes insulating sheets 61 and 62. As illustrated in FIG. 5 and FIG. 6, insulating sheet 61 (a first insulating sheet) is disposed below cooler 50 (that is, on the relay-10 side) and insulating sheet 62 (a second insulating sheet) is disposed above cooler 50 (that is, on the fuse-20 side). Thus, cooler 50 is located between insulating sheet 61 and insulating sheet 62. In the present embodiment, insulating sheet 61 is in close contact with a lower surface of passage 51 of cooler 50, and insulating sheet 62 is in close contact with an upper surface of passage 51 of cooler 50.

Insulating sheet 61, which is the lower insulating sheet, is disposed over the whole of cooler 50. Thus, insulating sheet 61 is disposed across the plurality of relays 10. Insulating sheet 61 is disposed also across the plurality of heatsinks 41, and is thus located between cooler 50 and the plurality of heatsinks 41. Note that insulating sheet 61 may be divided into a plurality of insulating sheets, or a part or whole of insulating sheet 61 may be a multi-layer insulating sheet.

Insulating sheet 62, which is the upper insulating sheet, is disposed opposite to fuse 20. In the present embodiment, insulating sheet 62 is disposed across the plurality of heatsinks 42 placed side by side with fuse 20, and is thus located between cooler 50 and each of fuse 20 and heatsink 42. Note that insulating sheet 62 may be divided into a plurality of insulating sheets, or a part or whole of insulating sheet 62 may be a multi-layer insulating sheet.

Each of insulating sheets 61 and 62 is a thin-sheeted insulating member made of an insulating material. Before placement, each of insulating sheets 61 and 62 has a uniform thickness. Each of insulating sheets 61 and 62 has at least a basic insulation function. In the present embodiment, insulating sheets 61 and 62 alone have a reinforced insulation function including an insulation function. Each of insulating sheets 61 and 62 is made of an insulating resin material, for example.

Furthermore, each of insulating sheets 61 and 62 may have a function of size adjustment by compression. To be more specific, insulating sheets 61 and 62 may be elastic sheets that are elastically deformable. In this case, elastomer may be used for making insulating sheets 61 and 62. With this, insulating sheets 61 and 62 that are elastically deformable can be obtained. For example, insulating sheets 61 and 62, which are the elastic sheets, are made of silicon rubber or acrylic rubber and thus have rubber elasticity.

Furthermore, each of insulating sheets 61 and 62 may have a heat transfer function. To be more specific, each of insulating sheets 61 and 62 may be made of a material having high heat conductivity. In this case, heat conducting sheets (thermal sheets) may be used as insulating sheets 61 and 62.

In the present embodiment, insulating sheets 61 and 62 have the reinforced insulation function and the heat transfer function, and also have the function of size adjustment by compression. In this case, insulating heat-conducting sheets made of elastomer may be used as insulating sheets 61 and 62. Note that each of insulating sheets 61 and 62 may have the basic insulation function and the heat transfer function.

As illustrated in FIG. 5 and FIG. 6, enclosure 70 accommodates the electronic components, such as relay 10 and fuse 20. Furthermore, enclosure 70 also accommodates busbar 30, heatsink 40, cooler 50, and insulating sheets 61 and 62. Enclosure 70 is an exterior frame member of battery disconnect unit 1. Thus, the whole outer surface of enclosure 70 is exposed to the outside air.

As illustrated in FIG. 2 to FIG. 6, enclosure 70 has upper cover 71 (a first cover) and lower cover 72 (a second cover). Lower cover 72 is a box-shaped case. The plurality of relays 10 are accommodated in lower cover 72. Cooler 50 is disposed to cover an opening part of lower cover 72. Fuse 20 disposed above cooler 50 is covered by upper cover 71.

Enclosure 70 is a resin member made of an insulating resin material. Examples of the resin material used for making enclosure 70 include polyphenylene sulfide (PPS) and polybutylene telephthalate (PBT). In the present embodiment, each of upper cover 71 and lower cover 72 is made of glass fiber reinforced PBT. Note that upper cover 71 and lower cover 72 need not be made of the same resin material and may be made of different resin materials.

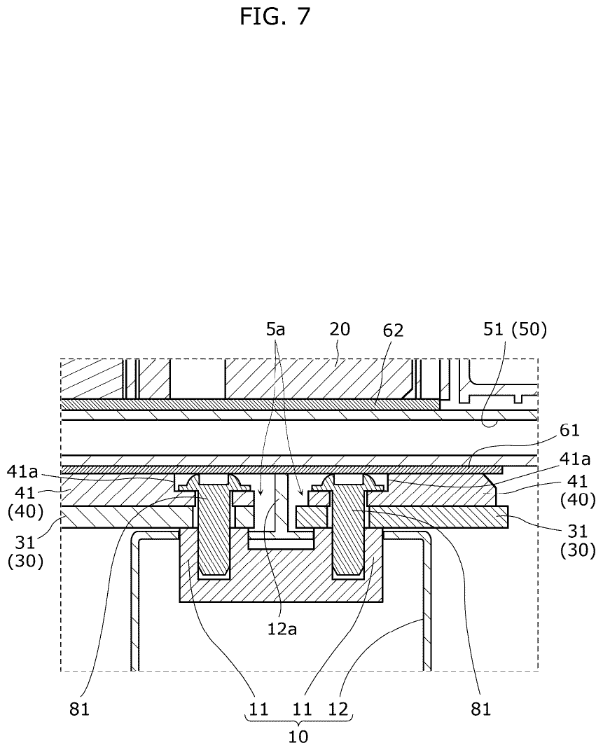

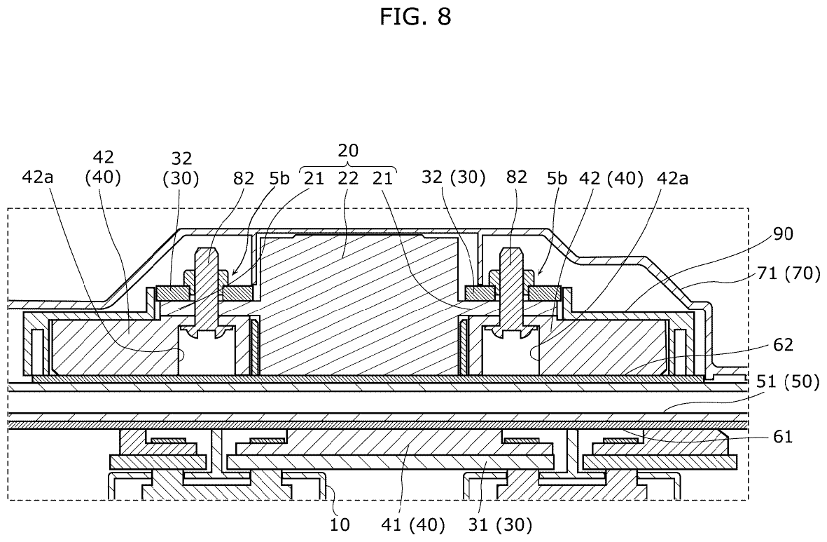

Hereafter, a characteristic structure of battery disconnect unit 1 according to the present embodiment is described with reference to FIG. 7 and FIG. 8. FIG. 7 is an enlarged cross-sectional view of region VII enclosed by the broken line in FIG. 5. FIG. 8 is an enlarged cross-sectional view of region VIII enclosed by the broken line in FIG. 6.

A characteristic structure around terminal 11 of relay 10 is described with reference to FIG. 7.

As illustrated in FIG. 7, terminal 11 of relay 10, busbar 31, and heatsink 41 are fastened with screw 81. To be more specific, terminal 11 of relay 10, busbar 31, and heatsink 41 are fastened together with screw 81. Screw 81 is an example of a fastening member. A vis or a bolt may be used as screw 81, for example.

Joint section 5a is a section in which terminal 11 of relay 10, busbar 31, and heatsink 41 are fastened together with screw 81. In joint section 5a, relay 10, busbar 31, and heatsink 41 are electrically and thermally connected to each other.

In the present embodiment, at each of the pair of terminals 11 of relay 10, terminal 11 of relay 10, busbar 31, and heatsink 41 are fastened together with screw 81. Thus, one relay 10 includes two joint sections 5a. Two joint sections 5a are included in each of the plurality of relays 10.

In joint section 5a, busbar 31 is located between terminal 11 of relay 10 and heatsink 41. Thus, terminal 11 of relay 10 is connected to heatsink 41 via busbar 31. To be more specific, busbar 31 and heatsink 41 are stacked above terminal 11 of relay 10, and thus busbar 31 is sandwiched between terminal 11 of relay 10 and heatsink 41. In this case, a lower surface of busbar 31 is in contact with terminal 11 of relay 10, and an upper surface of busbar 31 is in contact with a lower surface of heatsink 41.

As described above, battery disconnect unit 1 according to the present embodiment includes heatsink 41 disposed in a connection part between terminal 11 of relay 10 and busbar 31. With this, the heat capacity near terminal 11 of relay 10 increases. Thus, the heat from terminal 11 of relay 10 is conducted to heatsink 41 and then can be efficiently dissipated.

Furthermore, in the present embodiment, cooler 50 is disposed near joint section 5a in which terminal 11 of relay 10, busbar 31, and heatsink 41 are fastened together with screw 81. To be more specific, cooler 50 is disposed above joint section 5a.

With this, heatsink 41 is cooled by cooler 50. Thus, the heat of relay 10 that is conducted to heatsink 41 is cooled by cooler 50. In this way, battery disconnect unit 1 according to the present embodiment has a cooling structure that is excellent in cooling performance achieved by heatsink 41 and cooler 50. This enhances the cooling performance to respond to the heat of relay 10 and thereby effectively reduces a rise in temperature of relay 10. In particular, in response to short-time heat generation or larger currents in battery 2 of the electric vehicle, a rise in temperature of relay 10 can be effectively reduced. Furthermore, by enhancing the cooling performance with heatsink 41 and cooler 50, the thickness or length of busbar 31 can be reduced. This can achieve cost reduction.

Furthermore, heatsink 41 is additionally included in the present embodiment, and thus terminal 11 of relay 10, busbar 31, and heatsink 41 are fastened together with screw 81. With this, when terminal 11 of relay 10 and busbar 31 are connected to be fastened, heatsink 41 can also be fastened at the same time. In other words, the addition of heatsink 41 causes no additional work. Thus, a rise in temperature of relay 10 can be effectively reduced without affecting the workability.

Furthermore, battery disconnect unit 1 according to the present embodiment includes insulating sheet 61 located between cooler 50 and joint section 5a in which terminal 11 of relay 10, busbar 31, and heatsink 41 are fastened together with screw 81. To be more specific, insulating sheet 61 is sandwiched between heatsink 41 and cooler 50. Thus, insulating sheet 61 is disposed on a heat-dissipation surface of heatsink 41 (that is, the surface on the cooler-50 side).

Even when heatsink 41 made of metal is in contact with busbar 31, this structure can prevent conduction between terminal 11 of relay 10 and cooler 50 that includes passage 51 (pipe) made of metal. More specifically, insulating sheet 61 provides insulation between terminal 11 of relay 10 and cooler 50 by electrically separating terminal 11 of relay 10 from cooler 50. In particular, even for an electric vehicle including a high-voltage battery, insulation can be sufficiently provided.

In this case, if an insulating member is located between heatsink 41 and cooler 50, a distance between heatsink 41 and cooler 50 increases by the thickness of this insulating member. This can result in a decrease in the cooling effect of cooler 50 on heatsink 41, thereby inhibiting the transfer of the heat from relay 10 to cooler 50. In addition, battery disconnect unit 1 increases in size as the thickness of the insulating member increases. Thus, the addition of heatsink 41 may create a difficulty in enabling both heat dissipation of the heat of relay 10 and insulation in battery disconnect unit 1, and may also increase the size of battery disconnect unit 1.

In contrast, battery disconnect unit 1 according to the present embodiment includes insulation sheet 61, which is sheeted, to provide insulation between terminal 11 of relay 10 and cooler 50. With this, the insulation between terminal 11 of relay 10 and cooler 50 can be provided without increasing the size of battery disconnect unit 1 and without inhibiting the heat transfer from relay 10 to cooler 50.

As described thus far, battery disconnect unit 1 according to the present embodiment is capable of achieving downsizing of battery disconnect unit 1 while enabling both heat dissipation of the heat of relay 10 and insulation near relay 10. Furthermore, battery disconnect unit 1 according to the present embodiment enables the efficient heat transfer from relay 10 to cooler 50 and thereby can respond to even higher currents in battery 2.

Furthermore, in battery disconnect unit 1 according to the present embodiment, insulating sheet 61 located between heatsink 41 situated near relay 10 and cooler 50 has the basic insulation function and the heat transfer function. More specifically, insulating sheet 61 is an insulating heat-conducting sheet.

This structure allows the heat generated by relay 10 to be efficiently transferred to cooler 50 while providing insulation between relay 10 and cooler 50. Here, if the insulation between relay 10 and cooler 50 is insufficient by using only the basic insulation function of insulating sheet 61, the currents passing through relay 10 and busbar 31 may be conducted to cooler 50. In this case, insulation can be provided by additionally taking insulation measures using an external device connected to cooler 50, for example.

Furthermore, in battery disconnect unit 1 according to the present embodiment, insulating sheet 61 located between cooler 50 and heatsink 41 has the reinforced insulation function and the heat transfer function and also has the function of size adjustment by compression. More specifically, insulating sheet 61 is an insulating elastic sheet, and is in compression by being sandwiched between heatsink 41 and cooler 50.

With this structure, insulation is provided between relay 10 and cooler 50 only by insulating sheet 61. In addition, the heat of terminal 11 of relay 10 can be conducted more efficiently to cooler 50. More specifically, having the function of size adjustment by compression, insulating sheet 61 is able to absorb a dimensional tolerance of cooler 50, for example. This reduces clearance, which causes heat insulation, between heatsink 41 and cooler 50. Thus, the heat of terminal 11 of relay 10 can be efficiently conducted to cooler 50.

Furthermore, in battery disconnect unit 1 according to the present embodiment, heatsink 41 situated near relay 10 has recess 41a to accommodate the screw head of screw 81 as illustrated in FIG. 7. Recess 41a is a counterbore.

With this structure, the screw head of screw 81 can be accommodated in recess 41a and prevented from protruding to the cooler-50 side. Thus, a distance between heatsink 41 and cooler 50 can be reduced. This allows the heat of terminal 11 of relay 10 to be efficiently conducted to cooler 50. Moreover, the accommodation of the screw head of screw 81 in recess 41a eliminates an occurrence of an upward push by the screw head of screw 81 against cooler 50. Furthermore, the accommodation of the screw head of screw 81 in recess 41a enables a further downsizing of battery disconnect unit 1.

Furthermore, in battery disconnect unit 1 according to the present embodiment, heatsink 41 situated near relay 10 may have a thickness less than or equal to four times the thickness of busbar 31 connected to terminal 11 of relay 10.

Making the thickness of heatsink 41 at least equal to the thickness of busbar 31 allows heatsink 41 to have a sufficient heat capacity corresponding to the heat of terminal 11 of relay 10. However, heatsink 41 that is too thick increases a distance between terminal 11 of relay 10 and cooler 50 and can only reduce the dissipation of the heat of terminal 11 of relay 10. On this account, the thickness of heatsink 41 may be not more than four times the thickness of busbar 31.

Furthermore, in battery disconnect unit 1 according to the present embodiment, heatsink 41 situated near relay 10 is made of a material having a heat capacity higher than a heat capacity of case 12 of relay 10. To be more specific, heatsink 41 is made of copper or aluminum.

With this structure, the heat capacity of heatsink 41 can be increased. Thus, while being cooled by cooler 50, heatsink 41 with the high heat capacity is able to store large heat energy. This further enhances the dissipation of the heat of terminal 11 of relay 10. In particular, heatsink 41 is able to efficiently absorb the heat generated by relay 10 in the event of sudden acceleration of the electric vehicle. Furthermore, when the electric vehicle is running at a constant speed or decelerating to stop after the end of acceleration, the heat energy stored in heatsink 41 can be dissipated to cooler 50 via insulating sheet 61. In this way, battery disconnect unit 1 according to the present embodiment has a heat storage-dissipation structure that enables charge and discharge to respond to sudden acceleration of the electric vehicle.

Furthermore, the high-heat-capacity material used for heatsink 41 easily enables even heatsink 41 that is small in size to have a high heat capacity. Thus, downsizing of battery disconnect unit 1 can be easily achieved.

Furthermore, relay 10 of battery disconnect unit 1 according to the present embodiment includes insulating plate 12a located between the pair of terminals 11.

With this structure, a creepage distance for insulation between the pair of terminals 11 can be provided. This enhances insulation.

Furthermore, in battery disconnect unit 1 according to the present embodiment, the total thickness of heatsink 40 and busbar 31 connected to terminal 11 of relay 10 is greater than the height of insulating sheet 12a of relay 10.

With this structure, in battery disconnect unit 1 including cooler 50 disposed above relay 10 including insulating sheet 12a, busbar 31 and heatsink 41 that are stacked above terminal 11 of relay 10 can eliminate an occurrence of an upward push by insulating sheet 12a against cooler 50. Thus, the downsizing of battery disconnect unit 1 can be easily achieved while both heat dissipation and insulation are enabled.

A characteristic structure around terminal 21 of fuse 20 is described with reference to FIG. 8.

As illustrated in FIG. 8, terminal 21 of fuse 20, busbar 32, and heatsink 42 are fastened with screw 82. To be more specific, terminal 21 of fuse 20, busbar 32, and heatsink 42 are fastened together with screw 82. Screw 82 is an example of a fastening member. As with screw 81 (a first screw), a vis or a bolt may be used as screw 82 (a second screw), for example.

Joint section 5b is a section in which terminal 21 of fuse 20, busbar 32, and heatsink 42 are fastened together with screw 82. In joint section 5b, fuse 20, busbar 32, and heatsink 42 are electrically and thermally connected to each other.

In the present embodiment, at each of the pair of terminals 21 of fuse 20, terminal 21 of fuse 20, busbar 32, and heatsink 42 are fastened together with screw 82. Thus, one fuse 20 includes two joint sections 5b.

In joint section 5b, terminal 21 of fuse 20 is located between busbar 32 and heatsink 42. To be more specific, terminal 21 of fuse 20 and busbar 32 are stacked above heatsink 42, and thus terminal 21 of fuse 20 is sandwiched between busbar 32 and heatsink 42. In this case, one surface of terminal 21 of fuse 20 that is an upper surface (a busbar connection surface) is in contact with a lower surface of busbar 32, and the other surface of terminal 21 of fuse 20 that is a lower surface (a heatsink connection surface) is in contact with an upper surface of heatsink 42.

Note that heatsink 42 is held by holder 90. Holder 90 is fixed to a part of cooler 50 via a screw (not shown), for example.

As described above, battery disconnect unit 1 according to the present embodiment includes heatsink 42 disposed in a connection part between terminal 21 of fuse 20 and busbar 32. With this, the heat capacity near terminal 21 of fuse 20 increases. Thus, the heat from terminal 21 of fuse 20 is conducted to heatsink 42 and then can be efficiently dissipated.

Furthermore, in the present embodiment, cooler 50 is disposed near joint section 5b in which terminal 21 of fuse 20, busbar 32, and heatsink 42 are fastened together with screw 82. To be more specific, cooler 50 is disposed below joint section 5b.

With this, heatsink 42 is cooled by cooler 50. Thus, the heat of fuse 20 that is conducted to heatsink 42 is cooled by cooler 50. In this way, battery disconnect unit 1 according to the present embodiment has a cooling structure that is excellent in cooling performance achieved by heatsink 42 and cooler 50. This enhances the cooling performance to respond to the heat of terminal 21 of fuse 20 and thereby effectively reduces a rise in temperature of terminal 21 of fuse 20. In particular, in response to short-time heat generation or larger currents in battery 2 of the electric vehicle, a rise in temperature of terminal 21 of fuse 20 can be effectively reduced. Furthermore, by enhancing the cooling performance with heatsink 42 and cooler 50, the thickness or length of busbar 32 can be reduced. This can achieve cost reduction.

Furthermore, heatsink 42 is additionally included in the present embodiment, and thus terminal 21 of fuse 20, busbar 32, and heatsink 42 are fastened together with screw 82. With this, when terminal 21 of fuse 20 and busbar 32 are connected to be fastened, heatsink 42 can also be fastened at the same time. In other words, the addition of heatsink 42 causes no additional work. Thus, a rise in temperature of fuse 20 can be effectively reduced without affecting the workability.

Furthermore, battery disconnect unit 1 according to the present embodiment includes insulating sheet 62 located between cooler 50 and joint section 5b in which terminal 21 of fuse 20, busbar 32, and heatsink 42 are fastened together with screw 82. To be more specific, insulating sheet 62 is sandwiched between heatsink 42 and cooler 50. Thus, insulating sheet 62 is disposed on a heat-dissipation surface of heatsink 42 (that is, the surface on the cooler-50 side).

Even when heatsink 42 made of metal is in contact with busbar 32, this structure can prevent conduction between terminal 21 of fuse 20 and cooler 50 that includes passage 51 (pipe) made of metal. More specifically, insulating sheet 62 provides insulation between terminal 21 of fuse 20 and cooler 50 by electrically separating terminal 21 of fuse 20 from cooler 50. In particular, even for an electric vehicle including a high-voltage battery, insulation can be sufficiently provided.

In this case, if an insulating member is located between heatsink 42 and cooler 50, a distance between heatsink 42 and cooler 50 increases by the thickness of this insulating member. This can result in a decrease in the cooling effect of cooler 50 on heatsink 42, thereby inhibiting the transfer of the heat from fuse 20 to cooler 50. In addition, battery disconnect unit 1 increases in size as the thickness of the insulating member increases. Thus, the addition of heatsink 42 may create a difficulty in enabling both heat dissipation of the heat of fuse 20 and insulation in battery disconnect unit 1, and may also increase the size of battery disconnect unit 1.

In contrast, battery disconnect unit 1 according to the present embodiment includes insulation sheet 62, which is sheeted, to provide insulation between terminal 21 of fuse 20 and cooler 50. With this, the insulation between terminal 21 of fuse 20 and cooler 50 can be provided without increasing the size of battery disconnect unit 1 and without inhibiting the heat transfer from fuse 20 to cooler 50.

As described thus far, battery disconnect unit 1 according to the present embodiment is capable of achieving downsizing of battery disconnect unit 1 while enabling both heat dissipation of the heat of fuse 20 and insulation near fuse 20. Furthermore, battery disconnect unit 1 according to the present embodiment enables the efficient heat transfer from fuse 20 to cooler 50 and thereby can respond to even higher currents in battery 2.

Furthermore, in battery disconnect unit 1 according to the present embodiment, insulating sheet 62 located between heatsink 42 situated near fuse 20 and cooler 50 has the basic insulation function and the heat transfer function. More specifically, insulating sheet 62 is an insulating heat-conducting sheet.

This structure allows the heat generated by fuse 20 to be efficiently transferred to cooler 50 while providing insulation between fuse 20 and cooler 50. Here, if the insulation between fuse 20 and cooler 50 is insufficient by using only the basic insulation function of insulating sheet 62, the currents passing through fuse 20 and busbar 32 may be conducted to cooler 50. In this case, insulation can be provided by additionally taking insulation measures using an external device connected to cooler 50, for example.

Furthermore, in battery disconnect unit 1 according to the present embodiment, insulating sheet 62 located between cooler 50 and heatsink 42 has the reinforced insulation function and the heat transfer function and also has the function of size adjustment by compression. More specifically, insulating sheet 62 is an insulating elastic sheet, and is in compression by being sandwiched between heatsink 42 and cooler 50.

With this structure, insulation is provided between fuse 20 and cooler 50 only by insulating sheet 62. In addition, the heat of terminal 21 of fuse 20 can be conducted more efficiently to cooler 50. More specifically, having the function of size adjustment by compression, insulating sheet 62 is able to absorb a dimensional tolerance of cooler 50, for example. This reduces clearance, which causes heat insulation, between heatsink 42 and cooler 50. Thus, the heat of terminal 21 of fuse 20 can be efficiently conducted to cooler 50.

Furthermore, the use of an elastic sheet for insulating sheet 62 allows insulating sheet 62 to absorb the dimensional tolerance of heatsink 42 disposed on each of both sides of fuse 20. In addition, the use of an elastic sheet for insulating sheet 62 enhances vibration resistance of fuse 20. More specifically, insulating sheet 62 is able to reduce a vibration load on fuse 20 and thus enhance the durability of fuse 20.

Furthermore, in battery disconnect unit 1 according to the present embodiment, heatsink 42 situated near fuse 20 has recess 42a to accommodate the screw head of screw 82 as illustrated in FIG. 8. Recess 42a is a counterbore.

With this structure, the screw head of screw 82 can be accommodated in recess 42a and prevented from protruding to the cooler-50 side. Thus, a distance between heatsink 42 and cooler 50 can be reduced. This allows the heat of terminal 21 of fuse 20 to be efficiently conducted to cooler 50. Moreover, the accommodation of the screw head of screw 82 in recess 42a eliminates an occurrence of an upward push by the screw head of screw 82 against cooler 50. Furthermore, the accommodation of the screw head of screw 82 in recess 42a enables a further downsizing of battery disconnect unit 1.

Furthermore, in battery disconnect unit 1 according to the present embodiment, heatsink 42 situated near fuse 20 may have a thickness less than or equal to four times the thickness of busbar 32 connected to terminal 21 of fuse 20.

Making the thickness of heatsink 42 at least equal to the thickness of busbar 32 allows heatsink 42 to have a sufficient heat capacity corresponding to the heat of terminal 21 of fuse 20. However, heatsink 42 that is too thick increases a distance between terminal 21 of fuse 20 and cooler 50, and can only reduce the dissipation of the heat of terminal 21 of fuse 20. On this account, the thickness of heatsink 42 may be not more than four times the thickness of busbar 32.

Furthermore, in battery disconnect unit 1 according to the present embodiment, heatsink 42 situated near fuse 20 is made of a material having a heat capacity higher than a heat capacity of case 22 of fuse 20. To be more specific, heatsink 42 is made of copper or aluminum.

With this structure, the heat capacity of heatsink 42 can be increased. Thus, while being cooled by cooler 50, heatsink 42 with the high heat capacity is able to store large heat energy. This further enhances the dissipation of the heat of terminal 21 of fuse 20. Furthermore, the high-heat-capacity material used for heatsink 42 easily enables even heatsink 42 that is small in size to have a high heat capacity. Thus, downsizing of battery disconnect unit 1 can be easily achieved.

Furthermore, in battery disconnect unit 1 according to the present embodiment, the thickness of heatsink 42 situated near fuse 20 is the same length as the height from case 22 of fuse 20 to terminal 21 of fuse 20. Thus, no height difference is present between a lower surface of heatsink 42 and a lower surface of case 22 of fuse 20.

With this structure, each of the lower surface (heat-dissipation surface) of heatsink 42 and the lower surface of case 22 of fuse 20 is in contact with insulating sheet 62. Thus, each of the lower surface of heatsink 42 and the lower surface of case 22 of fuse 20 is in close contact with passage 51 of cooler 50 via insulating sheet 62. This increases a heat dissipation path of the heat generated by fuse 20 and thus enhances the heat dissipation responding to the heat generation of fuse 20.

Furthermore, battery disconnect unit 1 according to the present embodiment includes fuse 20 that is a current fuse. To be more specific, fuse 20 is a blow-type fuse, which blows if an excessive current flows through this fuse.

The inside of the blow-type fuse is filled with fine sand called arc-extinguishing sand. Vibration or shock to the fuse may cause the arc-extinguishing sand inside the fuse to leak to the outside. This can result in loss of the blow function of the fuse. In particular, in the event of vibration or shock to the blow-type fuse having an unstable joint between the busbar connected to the terminal of the blow-type fuse and the terminal of the blow-type fuse, or in the event of resonant vibration of the case of the fuse in response to the vibration or shock to the fuse, the arc-extinguishing sand inside the fuse is more likely to leak out.

In contrast, the elastic sheet as insulating sheet 62 located between cooler 50 and fuse 20 is able to absorb the vibration of fuse 20 as described above. With this, vibration stress of fuse 20 is reduced, and the arc-extinguishing sand inside fuse 20 is kept from leaking out. Thus, battery disconnect unit 1 according to the present embodiment that includes a blow-type fuse as fuse 20 is able to dissipate the heat of fuse 20, absorb the dimensional tolerance of fuse 20, and reduce the vibration of fuse 20. Hence, battery disconnect unit 1 with high reliability can be provided.

As described thus far, battery disconnect unit 1 according to the present embodiment is capable of achieving downsizing of battery disconnect unit 1 while enabling both heat dissipation and insulation.

Furthermore, battery disconnect unit 1 described above is suitable for use in an electric vehicle. In particular, battery disconnect unit 1 is more suitable for use in a pure electric vehicle, which uses larger currents than a hybrid electric vehicle.

### Variations

Although the technique according to the present disclosure has been described based on the embodiment, the present disclosure is not limited to the embodiment.

In the present embodiment, no height difference is present between the lower surface of heatsink 42 situated near fuse 20 and the lower surface of case 22 of fuse 20, and thus each of the lower surface of heatsink 42 and the lower surface of case 22 of fuse 20 is in contact with insulating sheet 62. However, this is not intended to be limiting. More specifically, a height difference may be present between the lower surface of heatsink 42 and the lower surface of case 22 of fuse 20.

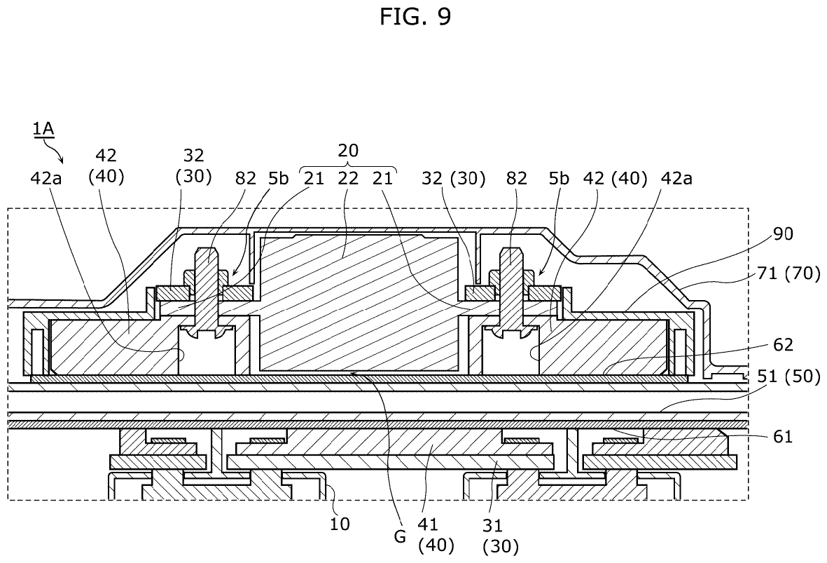

To be more specific, as in battery disconnect unit 1A illustrated in FIG. 9, the lower surface of heatsink 42 may be located closer to cooler 50 (that is, nearer insulating sheet 62) than the lower surface of case 22 is. This allows heatsink 42 to be nearer cooler 50, thereby enabling cooler 50 to efficiently cool the heat transferred to heatsink 42.

In this case, clearance G is present between the lower surface of case 22 of fuse 20 and insulating sheet 62 and thus insulating sheet 62 is not in contact with the lower surface of case 22 of fuse 20. However, this is not intended to be limiting. More specifically, insulating sheet 62 may be in contact not only with the lower surface of heatsink 42 but also with the lower surface of case 22 of fuse 20. In this case, insulating sheet 62 need not be of uniform thickness. Insulating sheet 62 may be a single-layer sheet that is partially thicker to fill in the height difference (difference in level) between heatsink 42 and case 22 of fuse 20. Alternatively, insulating sheet 62 may be a multi-layer sheet including a plurality of laminated insulating sheets to be partially thicker. Thus, even with the height difference between heatsink 42 and case 22 of fuse 20, each of the lower surface of heatsink 42 and the lower surface of case 22 of fuse 20 is able to be in close contact with cooler 50 via insulating sheet 62 without causing cooler 50 to have different heights.

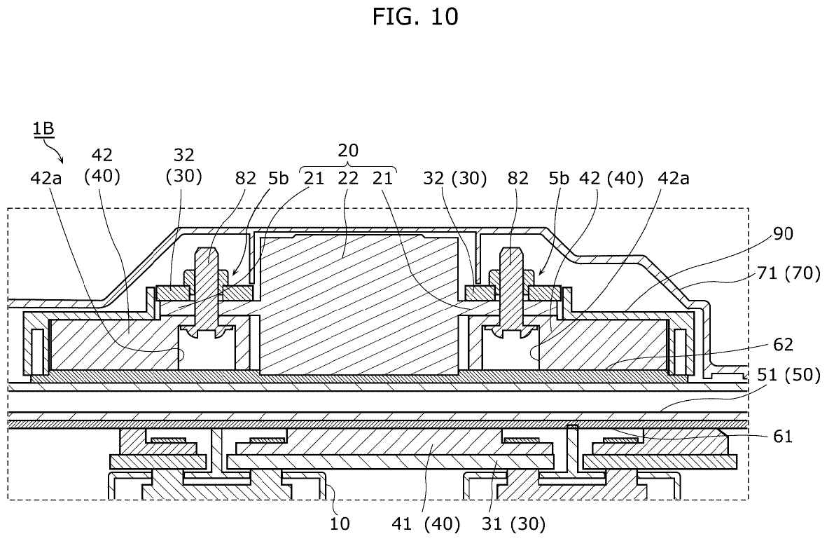

Furthermore, as in battery disconnect unit 1B illustrated in FIG. 10, a height difference may be present between the lower surface of heatsink 42 and the lower surface of case 22 of fuse 20, and the lower surface of case 22 of fuse 20 may be closer to cooler 50 (that is, nearer insulating sheet 62) than the lower surface of heatsink 42 is. In this case, insulating sheet 62 may be in close contact with each of the lower surface of heatsink 42 and the lower surface of case 22 of fuse 20, as illustrated in FIG. 10. For example, insulating sheet 62 need not be of uniform thickness. Insulating sheet 62 may be a single-layer sheet that is partially thicker to fill in the height difference (difference in level) between heatsink 42 and case 22 of fuse 20. Alternatively, insulating sheet 62 may be a multi-layer sheet including a plurality of laminated insulating sheets to be partially thicker. Thus, even with the height difference between heatsink 42 and case 22 of fuse 20, each of the lower surface of heatsink 42 and the lower surface of case 22 of fuse 20 is able to be in close contact with cooler 50 via insulating sheet 62 without causing cooler 50 to have different heights.

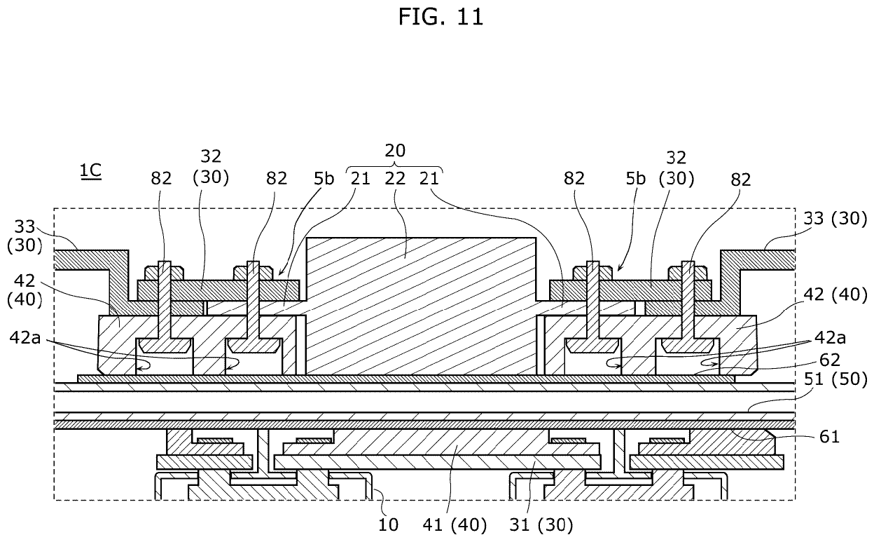

In the present embodiment, heatsink 42 situated near fuse 20 is stacked only on busbar 32 connected to terminal 21 of fuse 20 among the plurality of busbars 30. However, this is not intended to be limiting. For example, as in battery disconnect unit 1C illustrated in FIG. 11, heatsink 42 may be stacked not only on busbar 32 connected to terminal 21 of fuse 20 but also on busbar 33 connected to busbar 32, among the plurality of busbars 30. In this case, busbars 32 and 33 are connected to heatsink 42 with screws 82, as illustrated in FIG. 11. Here, heatsink 42 has two recesses 42a (counterbores) corresponding to two screws 82.

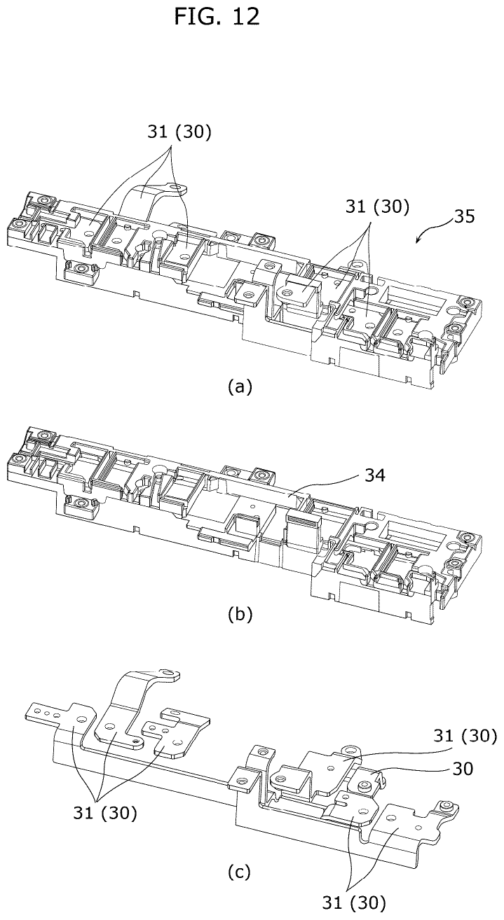

Although the plurality of busbars 30 are separate from each other in the present embodiment, this is not intended to be limiting. For example, as in module structure 35 illustrated in (a) of FIG. 12, busbars 31 connected to relay 10 among the plurality of busbars 30 may be integrated via insulating resin member 34. In this case, module structure 35 may include at least a pair of busbars 31 corresponding to pair of terminals 11 of relay 10. In module structure 35 according to the present variation, the plurality of busbars 30 (including all busbars 31) disposed below cooler 50 are integrated with insulating resin member 34. More specifically, module structure 35 illustrated in (a) of FIG. 12 is a result of integration of insulating resin member 34 illustrated in (b) with the plurality of busbars 30 illustrated in (c) of FIG. 12. In (b) of FIG. 12, only insulating resin member 34 of module structure 35 is illustrated.

Module structure 35 described above can be made by insert molding, for example. To be more specific, module structure 35 is made by fixing the plurality of busbars 31 integrally via insulating resin member 34 that is a mold resin. For example, a liquid resin material is injected into an injection mold in which the plurality of busbars 31 are placed, and is cured. This results in module structure 35 in which the plurality of busbars 31 are integrally embedded in insulating resin member 34 (the mold resin).

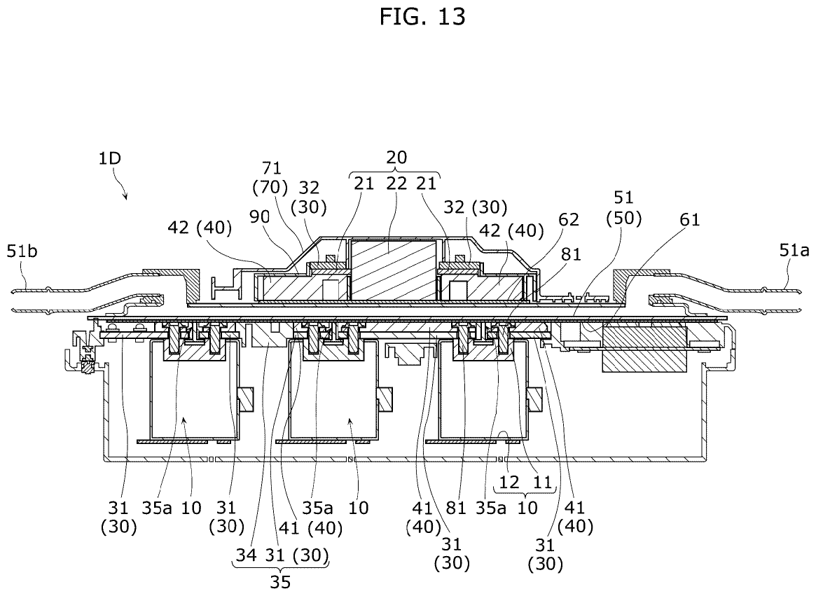

FIG. 13 is a cross-sectional view of battery disconnect unit 1D incorporating module structure 35 made as described above. Battery disconnect unit 1D illustrated in FIG. 13 is made by incorporating module structure 35 into battery disconnect unit 1 illustrated in FIG. 5. More specifically, busbars 30 of battery disconnect unit 1D illustrated in FIG. 13 are the same as busbars 30 of battery disconnect unit 1 illustrated in FIG. 5. Thus, battery disconnect unit 1D illustrated in FIG. 13 is different from battery disconnect unit 1 illustrated in FIG. 5 in that insulating resin member 34 is added.

As illustrated in FIG. 13, module structure 35 includes positioning section 35a disposed to allow insulating plate 12a of relay 10 to be located between the pair of busbars 31 corresponding to the pair of terminals 11 of relay 10. Positioning section 35a is disposed between a pair of heatsinks 41 connected to the pair of busbars 31. Thus, by simply placing module structure 35, a creepage distance is reliably provided between terminals 11 of the pair of relays 10 as well as between the pair of heatsinks 41. Note that, in module structure 35, not only the plurality of busbars 31 but also the plurality of heatsinks 41 may be integrated. More specifically, not only the plurality of busbars 31 but also the plurality of heatsinks 41 may be fixed to insulating resin member 34 of module structure 35.

Furthermore, although the coolant plate is used as cooler 50 in the present embodiment, this is not intended to be limiting. For example, cooler 50 may be any cooler other than a coolant plate.

Furthermore, although battery disconnect unit 1 is used in the electric vehicle in the present embodiment, this is not intended to be limiting. For example, battery disconnect unit 1 can also be applied to an electric appliance, such as a home electric appliance.

Those skilled in the art will readily appreciate that embodiments arrived at by making various modifications to the above embodiments or embodiments arrived at by selectively combining elements disclosed in the above embodiments without materially departing from the scope of the present disclosure may be included within one or more aspects of the present disclosure.

### INDUSTRIAL APPLICABILITY

The technology according to the present disclosure is widely applicable to various products, such as automobiles and electric appliances.

### REFERENCE SIGNS LIST

1, 1A, 1B, 1C, 1D battery disconnect unit
2 battery
3 inverter
5a, 5b joint section
10 relay
11, 21 terminal
12, 22 case
12a insulating plate
20 fuse
30, 31, 32, 33 busbar
34 insulating resin member
35 module structure
35a positioning section
40, 41, 42 heatsink
41a, 42a recess
50 cooler
51 passage
51a, 51b end opening
61, 62 insulating sheet
70 enclosure
71 upper cover
72 lower cover
81, 82 screw
90 holder
100 drive system

1. A battery disconnect unit comprising:
a fuse;
a busbar connected to a terminal of the fuse; and
a heatsink that is in contact with the terminal of the fuse,
wherein the terminal of the fuse is located between the busbar and the heatsink, and
the terminal of the fuse, the busbar, and the heatsink are fastened together by a fastening member.

2. The battery disconnect unit according to claim 1,
wherein the terminal of the fuse, the busbar, and the heatsink are electrically and thermally connected to each other.

3. The battery disconnect unit according to claim 1, further comprising:
a coolant plate,
wherein a lower surface of the heatsink is located closer to the coolant plate than a lower surface of a case of the fuse is.

4. The battery disconnect unit according to claim 1, further comprising:
an insulating sheet located between the heatsink and the coolant plate.

5. The battery disconnect unit according to claim 4,
wherein a lower surface of the heatsink and a lower surface of a case of the fuse have a height difference, and
the insulating sheet is in contact with each of the lower surface of the heatsink and the lower surface of the case of the fuse.

6. The battery disconnect unit according to claim 4,
wherein the insulating sheet is an insulating heat-conducting sheet.

7. The battery disconnect unit according to claim 4,
wherein the insulating sheet is an insulating elastic sheet.

8. The battery disconnect unit according to claim 1,
wherein the heatsink comprises a material having a heat capacity higher than a heat capacity of a case of the fuse.

9. The battery disconnect unit according to claim 1,
wherein the fuse is a current fuse.

10. The battery disconnect unit according to claim 1,
wherein the battery disconnect unit is provided to an electric vehicle.
